(19) United States
(12) Patent Application Publication
(10) Pub. No.: US 2005/0272258 A1
(43) Pub. Date: Dec. 8, 2005

(54) Method of manufacturing a semiconductor device and semiconductor device

(76) Inventors: Toshiyuki Morita, Kawasaki-shi (JP); Hiroshi Toyoda, Kamakura-shi (JP); Yoshitaka Matsui, Oita-shi (JP); Fumitoshi Ikegaya, Ebina-shi (JP); Atsuko Sakata, Yokohama-shi (JP); Tomio Katata, Yokohama-shi (JP); Seiichi Omoto, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/143,449

(22) Filed: Jun. 3, 2005

(30) Foreign Application Priority Data
Jun. 4, 2004 (JP) P2004-167763
May 23, 2005 (JP) P2005-149505

(51) Int. Cl. H01L 31/00

(52) U.S. Cl. 438/660

(57) ABSTRACT

According to one aspect of the present invention, provided is a method of manufacturing a semiconductor device, including: forming a first metal film on a substrate having a recessed portion in a surface thereof, by a plating method so as to bury the first metal film in at least part of the recessed portion; forming a second metal film on the first metal film by a film deposition method different from the plating method, the second metal film including, as a main component, a metal that is a main component of the first metal film and containing an impurity whose concentration is lower than concentration of an impurity contained in the first metal film; heat-treating the first and second metal films; and removing the first and second metal films except portions buried in the recessed portion.

### CROSS-REFERENCE TO RELATED APPLICATION

This application is based upon and claims the benefit of priority from the prior Japanese Patent Application No.2004-167763, filed on Jul. 4, 2004 and the prior Japanese Patent Application No. 2005-149505 filed on May 23, 2005; the entire contents of which are incorporated herein by reference.

### BACKGROUND OF THE INVENTION

1. Field of the Invention

The present invention relates to a method of manufacturing a semiconductor device and a semiconductor device.

2. Description of the Related Art

As a material of wiring of a semiconductor device, Cu has recently come into use instead of Al in order to lower wiring resistance and improve resistance against migration such as electro migration (EM) and stress migration (SM) that may cause faulty wiring.

Unlike Al, Cu is difficult to process by RIE (reactive ion etching). Therefore, for forming wiring by Cu, a damascene method is used in which trenches or holes are formed in a surface of an insulation film in advance, a Cu film is formed on the insulation film so as to bury Cu in the trenches or holes, and unnecessary portions of the Cu film are thereafter removed by CMP (chemical mechanical polishing) to thereby form the wiring.

As a method of forming the Cu film in the damascene method, a plating method allowing bottom-up deposition is used. In a plating solution used here, predetermined amounts of three kinds of additives, namely, an accelerator, a suppressor, and a leveler are mixed, and the effect of the additives realizes the bottom-up deposition.

However, if the additives are mixed in the plating solution, impurities are mixed in the Cu film. This problem is correlated with film deposition rate, and more impurities are mixed in wide wiring trenches in which the bottom-up deposition is difficult to occur than in narrow wiring trenches in which the bottom-up deposition prominently occurs. A measure for reducing impurities is desired since the impurities in the wide wiring trenches will be a factor to cause a defect.

### SUMMARY OF THE INVENTION

According to one aspect of the present invention, provided is a method of manufacturing a semiconductor device, including: forming a first metal film on a substrate having a recessed portion in a surface thereof, by a plating method so as to bury the first metal film in at least part of the recessed portion; forming a second metal film on the first metal film by a film deposition method different from the plating method, the second metal film including, as a main component, a metal that is a main component of the first metal film and containing an impurity whose concentration is lower than concentration of an impurity contained in the first metal film; heat-treating the first and second metal films; and removing the first and second metal films except portions buried in the recessed portion after the heat treatment.

According to another aspect of the present invention, provided is a method of manufacturing a semiconductor device, including: immersing a substrate having a recessed portion in a surface thereof, in a plating solution in a plating solution bath, and supplying the plating solution into the plating solution bath at a supply rate of 15 L/min or higher while rotating the substrate at a rotation speed of 50 rpm or lower, thereby forming a metal film on the substrate by a plating method so as to bury the metal film in at least part of the recessed portion; and removing the metal film except a portion buried in the recessed portion.

According to still another aspect of the present invention, provided is a semiconductor device including: a substrate; an insulation film formed above the substrate and having a first recessed portion and a second recessed portion in a same surface; a first wiring buried in the first recessed portion and having a line width of 0.3 μm or less; and a second wiring buried in the second recessed portion, having a line width of more than 0.3 μm, and containing an impurity whose concentration is lower than concentration of an impurity contained in the first wiring.

### BRIEF DESCRIPTION OF THE DRAWINGS

FIG. 1 is a flowchart showing a flow of manufacturing processes of a semiconductor device according to a first embodiment.

FIG. 2A to FIG. 2H are schematic views showing the manufacturing processes of the semiconductor device according to the first embodiment.

FIG. 3 is a flowchart showing a flow of manufacturing processes of a semiconductor device according to a second embodiment.

FIG. 4 is a schematic view showing the manufacturing processes of the semiconductor device according to the second embodiment.

FIG. 5 is a schematic view showing a forming process of a plating film according to the second embodiment.

FIG. 6 is a graph showing the correlation of the concentrations of Cu ions and additives relative to the distance from a surface of a wafer in plating by supplying a plating solution at a supply rate of 15 L/min or higher while rotating the wafer at a rotation speed of 50 rpm or lower.

FIG. 7 is a graph showing the correlation of the concentrations of Cu ions and additives relative to the distance from a surface of a wafer in plating by supplying a plating solution at a supply rate of 15 L/min or higher while rotating the wafer at a rotation speed of about 100 rpm.

FIG. 8 is a graph showing the correlation of the concentrations of Cu ions and additives relative to the distance from a surface of a wafer in plating by supplying a plating solution at a supply rate of lower than 15 L/min while rotating the wafer at a rotation speed of 50 rpm or lower.

FIG. 9 is a graph showing the correlation between the rotation speed of a wafer and defect density according to an experimental example 2.

FIG. 10A to FIG. 10N are schematic views showing manufacturing processes of a semiconductor device according to a third embodiment.

FIG. 11A is a view schematically showing a state of an interface between a wide wiring and a barrier metal film when a main component of the wide wiring is Cu and the barrier metal film is composed of Ti, according to the third embodiment, and FIG. 11B is a view schematically showing a state of an interface between a wide wiring and a barrier metal film when a main component of the wide wiring is Cu and the barrier metal film is composed of Ta.

### DETAILED DESCRIPTION OF THE INVENTION

### First Embodiment

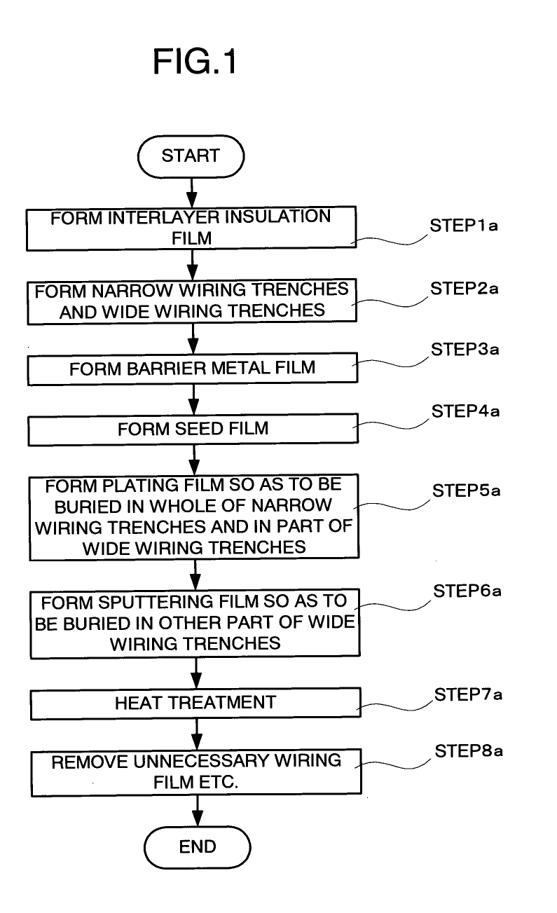

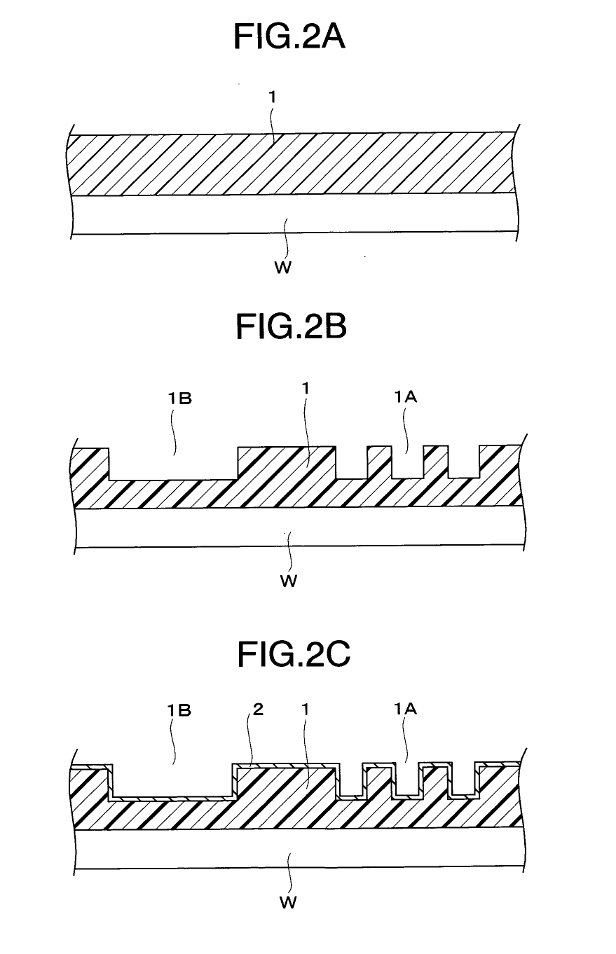

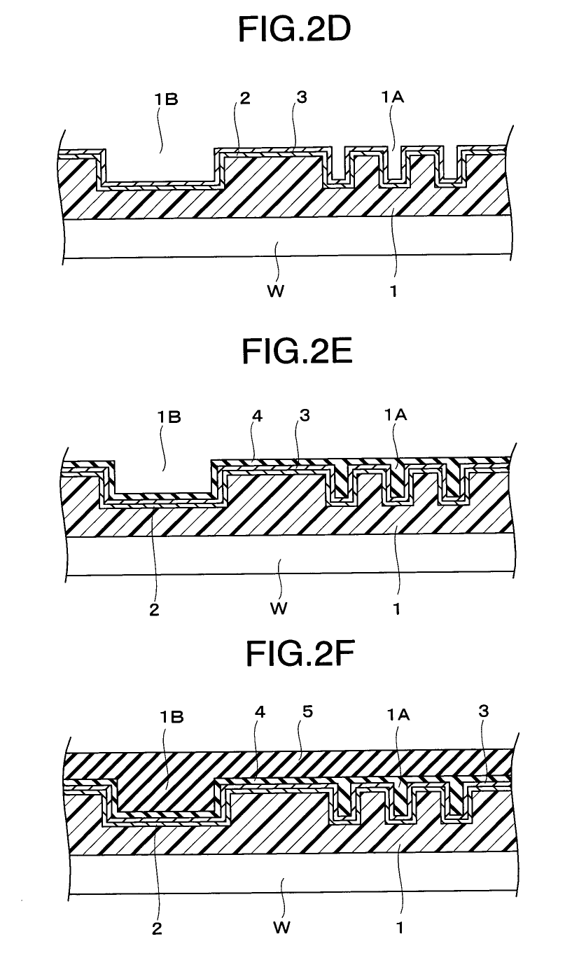

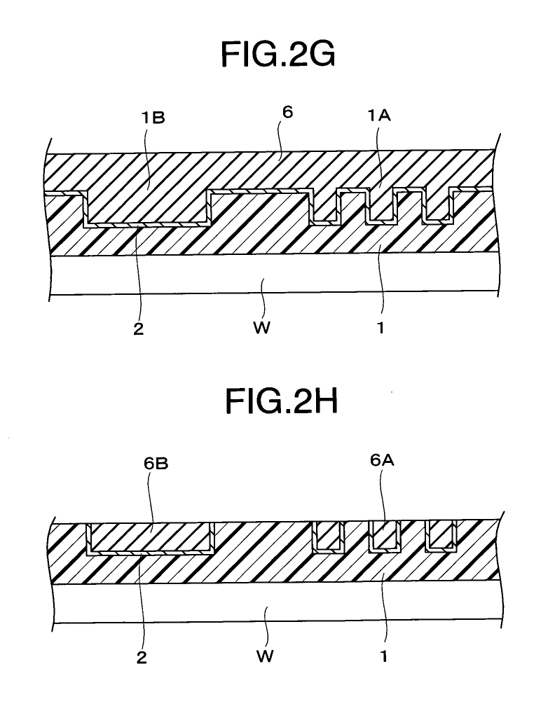

Hereinafter, a first embodiment will be described. FIG. 1 is a flowchart showing a flow of manufacturing processes of a semiconductor device according to this embodiment, and FIG. 2A to FIG. 2H are schematic views showing the manufacturing processes of the semiconductor device according to this embodiment. formed on a semiconductor wafer W (hereinafter, simply referred to as a “wafer”) by, for example, chemical vapor deposition (CVD) or coating (Step 1a). Examples of a material composing the interlayer insulation film 1 are a low dielectric constant insulation film such as an organic Si oxide film, an organic resin film and a porous Si oxide film, a SiO₂ film and so on.

After the interlayer insulation film 1 is formed, narrow wiring trenches 1A each with a width of 0.3 μm or less and wide wiring trenches 1B each with a width of more than 0.3 μm are formed in the interlayer insulation film 1 as shown in FIG. 2B, by a photolithography technique and reactive ion etching (RIE) (Step 2a). In order to form the narrow wiring trenches 1A and the wide wiring trenches 1B, an antireflection film and a chemically amplified photoresist are applied on the interlayer insulation film 1 while the wafer W is being rotated. After the photoresist is applied, it is exposed with ultraviolet light, using a mask with a predetermined pattern formed thereon. Thereafter, it is developed with a developing solution, so that a resist pattern is formed on the interlayer insulation film 1. After the resist pattern is formed on the interlayer insulation film 1, the interlayer insulation film 1 is etched by RIE with a mask used as a resist pattern, so that the narrow wiring trenches 1A and the wide wiring trenches 1B are formed in the interlayer insulation film 1. After the narrow wiring trenches 1A and the wide wiring trenches 1B are formed in the interlayer insulation film 1, the resist and the antireflection film are removed by ashing or the like.

After the narrow wiring trenches 1A and the wide wiring trenches 1B are formed in the interlayer insulation film 1, a barrier metal film 2 for suppressing metal diffusion to the interlayer insulation film 1 is formed on the interlayer insulation film 1 as shown in FIG. 2C, by, for example, sputtering or CVD (Step 3a). Examples of a material composing the barrier metal film 2 are conductive materials such as Ta, Ti, TaN, TiN, NbN, WN, and VN. The barrier metal film 2 may be formed of a stack of these materials.

After the barrier metal film 2 is formed on the interlayer insulation film 1, a seed film 3 for passing electric current at the time of electrolytic plating is formed on the barrier metal film 2 as shown in FIG. 2D, by, for example, sputtering (Step 4a). A metal such as Cu is an example of a material composing the seed film 3.

After the seed film 3 is formed on the barrier metal film 2, a plating solution is supplied to a surface of the seed film 3 and at the same time, electric current is supplied to the seed film 3, so that a plating film (first metal film) 4 is formed on the seed film 3 as shown in FIG. 2E, by electrolytic plating (Step 5a). In the plating solution, predetermined amounts of additives such as an accelerator, a suppressor, and a leveler are mixed in addition to metal ions such as, for example, Cu ions. Further, the plating film 4 is formed so as to be buried in the whole of each of the narrow wiring trenches 1A in which bottom-up deposition prominently occurs and in part of each of the wide wiring trenches 1B in which bottom-up deposition is difficult to occur. The plating film 4 is mainly composed of a metal such as Cu, but impurities are mixed therein. The “impurity” here is a substance containing at least one of S, Cl, O, C, and N.

After the plating film 4 is formed on the seed film 3, a. sputtering film (second metal film) 5 is formed to a thickness of, for example, about 500 nm on the plating film 4 as shown in FIG. 2F, by, for example, sputtering (Step 6a). The sputtering film 5 can be formed by using a target having high purity in high vacuum and Ar gas. The sputtering film 5 is formed so as to be buried in other part of each of the wide wiring trenches 1B. A main component of the sputtering film 5 is the same metal as the metal of the main component of the plating film 4.

The concentration of impurities (hereinafter, referred to as “impurity concentration”) in the sputtering film 5 is lower than the impurity concentration in the plating film 4. Here, that the impurity concentration in the sputtering film 5 is lower than the impurity concentration in the plating film 4 means that the concentration of a component with the highest concentration among at least one of S, Cl, O, C, and N existing in the sputtering film is lower than the concentration of a component with the highest concentration among at least one of S, Cl, O, C, and N existing in the plating film 4. The impurity concentration can be measured by, for example, secondary ion mass spectrometry (SIMS). The concentration of the component with the highest concentration among at least one of S, Cl, O, C, and N existing in the sputtering film 5 is preferably 1.00×10¹⁷ atom/cm³ or lower.

Incidentally, in this embodiment, the sputtering film 5 is formed by sputtering, but any film deposition method, if capable of forming a film with lower impurity concentration than that in the plating film 4, may be used in place of the sputtering. An example of such a film deposition method is CVD.

After the sputtering film 5 is formed on the plating film 4, the wafer W is heat-treated and crystals of the seed film 3, the plating film 4, and the sputtering film 5 are grown, so that a wiring film 6 is formed as shown in FIG. 2G (Step 7a). Here, when the wafer W is heat-treated, the impurities in the plating film 4 diffuse into the sputtering film 5 to get uniform. The heat treatment is conducted, for example, at 150° C. to 300° C. for 30 seconds to 60 minutes.

After the wafer W is heat-treated, polishing by, for example, chemical mechanical polishing (CMP) is performed so as to remove unnecessary portions of the barrier metal film 2 and the wiring film 6 on the interlayer insulation film 1 but leave the barrier metal film 2 and the wiring film 6 existing in the narrow wiring trenches 1A and the wide wiring trenches 1B, as shown in FIG. 2H (Step 8a). Specifically, slurry (not shown) is supplied on the wafer W while the wafer W and a polishing pad (not shown) are being rotated, with the wafer W being in contact with the polishing pad. Thereby, the wiring film 6 and so on are polished. A method of such polishing is not limited to CMP but other method may be used. An example of the other method is electrolytic polishing.

Through these processes, narrow wirings (first wiring) 6A each with a line with of 0.3 μm or less and wide wirings (second wiring) 6B each with a line width of more than 0.3 μm are formed. At this time, the impurity concentration in the obtained wide wirings 6B is lower than the impurity concentration in the narrow wirings 6A. This is because the wide wirings 6B are formed of the seed film 2, the plating film 4, and the sputtering film 5 with lower impurity concentration than that in the plating film 4, while the narrow wirings 6A are formed of the seed film 2 and the plating film 4.

Here, as the impurity concentrations of the respective narrow wirings 6A and wide wirings 6B, it is preferable that the impurity concentration in the narrow wirings 6A is substantially in a range from 5×10¹⁸ atom/cm³ to 1×10¹⁹atom/cm³, and the impurity concentration in the wide wirings 6B is substantially in a range lower than about 5×10¹⁶ atom/cm³. That is, if the impurity concentration in the narrow wirings 6A is too low, pinning of holes in the wirings by the impurities is not very much expected, and if the impurity concentrations in the narrow wirings 6A and the wide wirings 6B are too high, departing from the aforesaid ranges respectively, a defect due to aggregation of the impurities is more probable to occur. In this embodiment, for example, it is preferable that the impurity concentration in the narrow wirings 6A each with a line width of not less than 0.05 μm nor larger than 0.3 μm in which bottom-up deposition occurs prominently at the time of plating film deposition is set to 5×10¹⁸ atom/cm³ to 1×10¹⁹ atom/cm³, and the impurity concentration in the wide wirings 6B each with a line width of more than 0.3 μm and not more than 10 μm which is formed in the same surface as the narrow wirings 6A is set to lower than 5×10¹⁸ atom/cm³. The impurity concentration here can be also defined as the concentration of a component with the highest concentration among at least one of S, Cl, O, C, and N existing in each of the narrow wirings 6A and the wide wirings 6B.

According to this embodiment, it is possible to lower the impurity concentration in the wide wiring trenches 1B, which makes it possible to form the wide wirings 6B with a reduced number of defects. A possible reason why the existence of the impurities in the wide wiring trenches 1B causes a defect is as follows. Specifically, in the narrow wiring trenches 1A in which the bottom-up deposition occurs prominently, even if an excessive amount of the additives are supplied thereto, the impurity concentration does not get higher owing to a high film deposition rate of the plating film 4, but in the wide wiring trenches 1B in which the bottom-up deposition is difficult to occur, the excessive supply of the additives increases the impurity concentration. This is thought to cause the occurrence of defects in portions of the impurity aggregation in the wide wiring trenches 1B in accordance with the progress of the crystal growth in the heat treatment process.

In this embodiment, since the sputtering film 5 with lower impurity concentration than that in the plating film 4 is formed on the plating film 4, it is possible to diffuse the impurities contained in the plating film 4 into the sputtering film 5 in the heat treatment process. This can lower the impurity concentration in the wide wiring trenches 1B to allow the formation of the wide wirings 6B with a reduced number of defects, so that it is possible to provide a semiconductor device with improved wiring reliability.

Moreover, according to this embodiment, the plating film 4 is formed so as to be buried in part of each of the wide wiring trenches 1B and the sputtering film 5 is thereafter formed so as to be buried in the other portions of the wide wiring trenches 1B, which can reduce the impurities in the wide wiring trenches 1B, compared with a case where the plating film 4 is buried in the whole of the wide wiring trenches 1B. This makes it possible to form the wide wirings 6B with a reduced number of defects.

Further, according to this embodiment, the width of each of the narrow wiring trenches 1A is 0.3 μm or less and the plating film 4 is buried in the whole of the narrow wiring trenches 1A, which ensures that the plating film 4 is buried in the narrow wiring trenches 1A by the bottom-deposition. Note that the bottom-up deposition is thought to occur prominently in a trench with a width of 0.3 μm or less. Further, in such narrow wirings 6A, the progress of the crystal growth is restricted to the width of the narrow wiring trenches 1A or less, so that a defect ascribable to impurity aggregation accompanying the crystal growth is less probable to occur.

Rather, according to this embodiment, the existence of a certain amount of the impurities in the narrow wirings 6A makes it possible to pin the holes in the narrow wirings 6A to prevent the holes from migrating in the narrow wirings 6A. This can inhibit generation of a large void in the wiring that will be a cause of wire breakage or resistance increase, so that it is possible to provide a semiconductor device with improved wiring reliability.

### EXPERIMENTAL EXAMPLE 1

Hereinafter, an experiment example 1 will be described. In this experimental example, the impurity concentration in Cu films was measured and defect density in Cu wirings was measured.

In this experimental example, wafers formed by the following processes were used. After an oxide film was formed to a thickness of 20 nm on each Si substrate having an active portion, a SiOC-based low dielectric constant insulation film (interlayer insulation film) was formed to a thickness of 300 nm by CVD. Thereafter, wiring trenches (wide wiring trenches) each with a width of 4 μm and a depth of 250 nm were formed by lithography processes and RIE processes. Then, after resist removal by a wet etching process, a Ta film (barrier metal film) and a Cu film (seed film) were formed to 30 nm and 80 nm respectively by long throw sputtering. Next, by two kinds of film deposition methods, Cu films were formed. In a condition 1, a Cu film (plating film) was formed to a thickness of 210 nm by electrolytic plating under an electric current condition of 1A/wafer. Further, in a condition 2, a Cu film (plating film) was formed to a thickness of 10nm by electrolytic plating under an electric current condition of 1A/wafer, and thereafter, a Cu film (sputtering film) was formed to a thickness of 200 nm by long throw sputtering. Then, these wafers were subjected to 40-minute heat treatment at 270° C. in forming gas whose hydrogen concentration was about 10 vol %, and thereafter, unnecessary portions of the Cu films and so on were removed by CMP, so that Cu wirings were formed.

Then, the impurity concentration in each of the Cu films was measured and defect density in each of the Cu wirings was measured, using such wafers. In the measurement of the impurity concentration, SIMS was used to measure the concentrations of Cl, O, and C in the Cu films before the unnecessary portions of the Cu films and so on were removed by CMP. In the measurement of the defect density, a defect inspector was used to measure the defect density of each of the Cu wirings.

The results will be discussed below. Table 1 shows the impurity concentration in the Cu films and the defect density in the Cu wirings under the condition 1 and the condition 2.

TABLE 1

| | Condition 1 | Condition 2 |
|---|---|---|
| Cl Impurity Concentration (atom/cm³) | 1.00 × 10¹⁹ | 1.30 × 10¹⁶ |
| O Impurity Concentration (atom/cm³) | 2.00 × 10¹⁹ | 5.00 × 10¹⁵ |
| C Impurity Concentration (atom/cm³) | 1.50 × 10¹⁹ | 1.50 × 10¹⁶ |
| Defect Density | 1500 | 2 |

As shown in Table 1, the impurity concentration in the Cu film under the condition 2 was reduced by nearly about 3 digits compared with that under the condition 1 which is a normal condition. Accordingly, the defect density in the Cu wiring was greatly decreased. It has been confirmed from these results that forming a Cu film by sputtering after forming a Cu film by plating realizes lowered impurity concentration in the Cu film and lowered defect density in the Cu wiring. Incidentally, in this experimental example, the Cu wiring is described, but the same effects are obtainable in an Ag wiring and an Au wiring, if an Ag sputtering film, an Au sputtering film, or the like are formed on an Ag plating film and an Au plating film respectively.

### Second Embodiment

Hereinafter, a second embodiment will be described. This embodiment will describe an example where a plating film is formed by supplying a plating solution at a supply rate of 15 L/min or higher while rotating a wafer at a rotation speed of 50 rpm or lower. Some of the same contents as those in the first embodiment will be omitted.

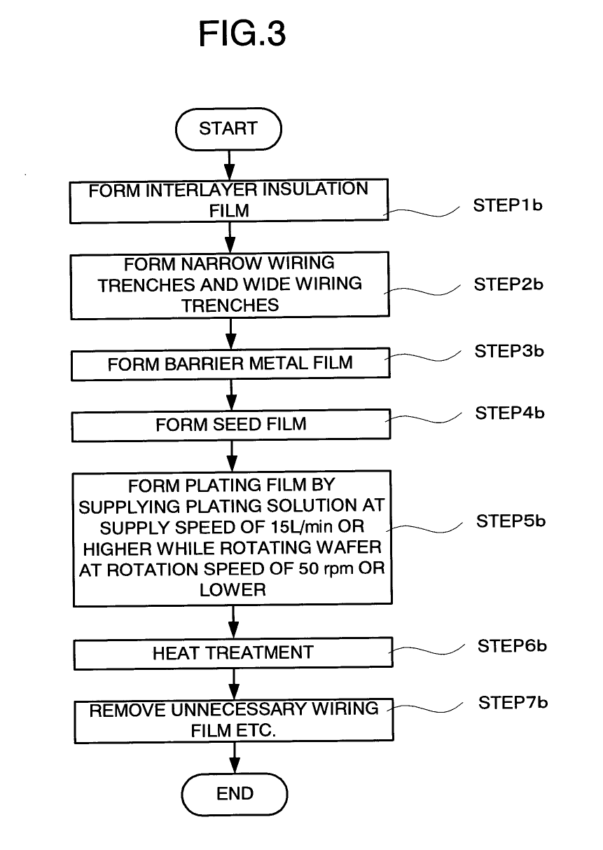

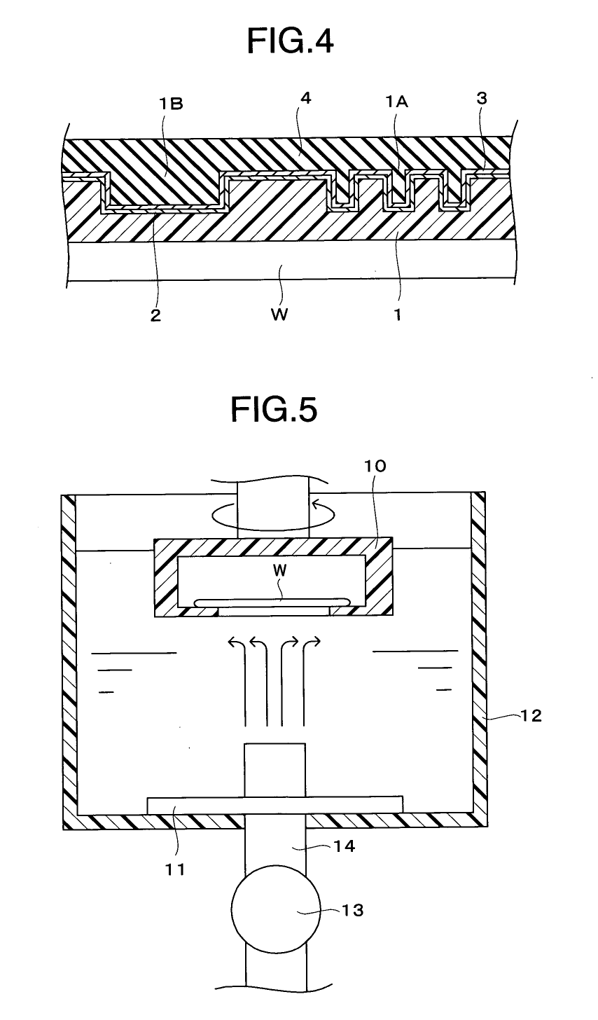

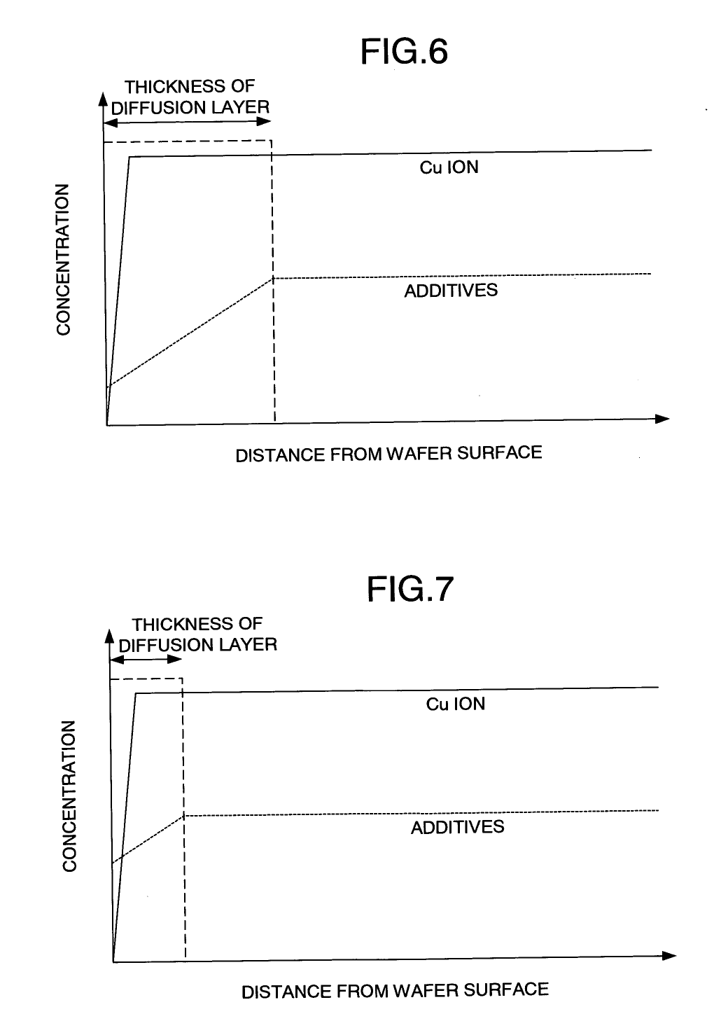

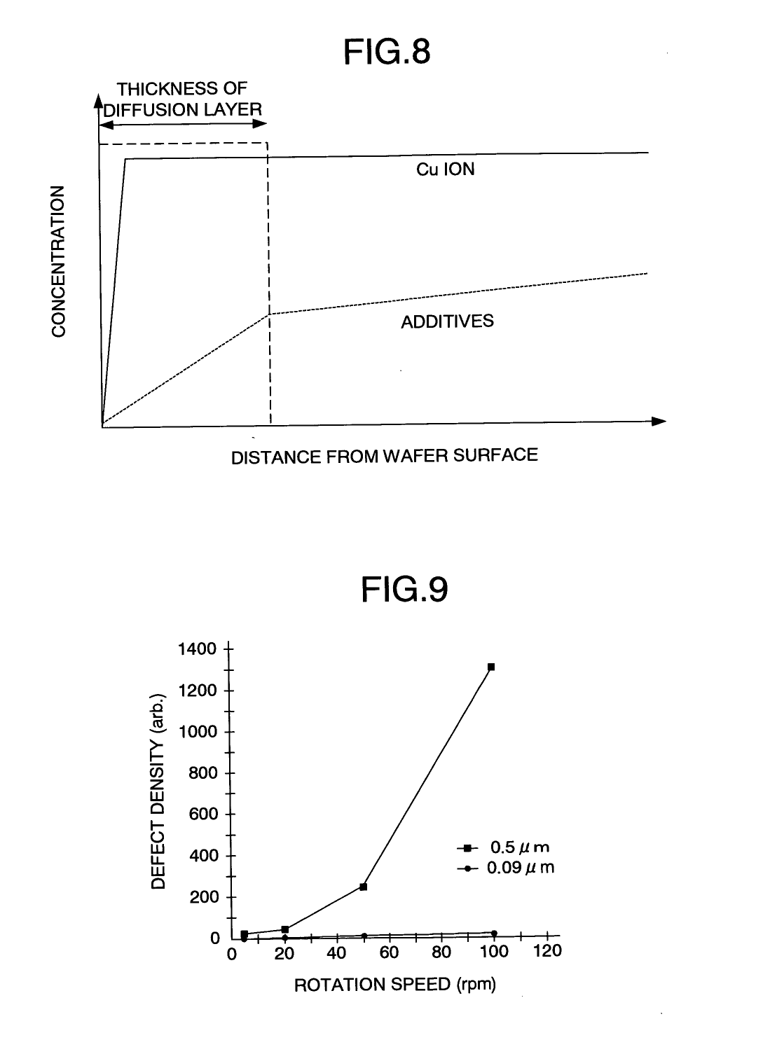

FIG. 3 is a flowchart showing a flow of manufacturing processes of a semiconductor device according to this embodiment, FIG. 4 is a schematic view showing the manufacturing processes of the semiconductor device according to this embodiment, FIG. 5 is a schematic view showing a forming process of a plating film according to this embodiment, FIG. 6 shows the correlation of the concentrations of Cu ions and additives relative to the distance from a surface of a wafer in plating by supplying a plating solution at a supply rate of 15 L/min or higher while rotating the wafer at a rotation speed of 50 rpm or lower, FIG. 7 shows the correlation of the concentrations of Cu ions and additives relative to the distance from a surface of a wafer in plating by supplying a plating solution at a supply rate of 15 L/min or higher while rotating a wafer at a rotation speed of about 100 rpm, and FIG. 8 shows the correlation of the concentrations of Cu ions and additives relative to the distance from a surface of a wafer in plating by supplying a plating solution at a supply rate of lower than 15 L/min while rotating the wafer at a rotation speed of 50 rpm or lower.

As shown in FIG. 3, an interlayer insulation film 1 is formed on a wafer W (Step 1b). After the interlayer insulation film 1 is formed, narrow wiring trenches 1A and wide wiring trenches 1B are formed in the interlayer insulation film 1 by a photolithography technique and reactive ion etching (RIE) (Step 2b).

After the narrow wiring trenches 1A and the wide wiring trenches 1B are formed in the interlayer insulation film 1, a barrier metal film 2 is formed on the interlayer insulation film 1 (Step 3b). After the barrier metal film 2 is formed on the interlayer insulation film 1, a seed film 3 is formed on the barrier metal film 2 (Step 4b).

After the seed film 3 is formed on the barrier metal film 2, a plating solution is supplied to a surface of the seed film 3, so that a plating film 4 is formed by electrolytic plating as shown in FIG. 4 (Step 5b). In this embodiment, the plating film 4 is formed so as to be buried in the whole of each of the narrow wiring trenches 1A and the whole of each of the wide wiring trenches 1B.

In order to form the plating film 4, voltage is applied between the wafer W serving as a cathode and an anode 11 while the wafer W is held by a holder 10 with the seed film 3 being set on a lower surface side, as shown in FIG. 5. Thereafter, the wafer W is slanted and immersed in the plating solution flowing in jet at a supply rate of 15 L/min or higher in a plating solution bath 12. At this time, the wafer W is preferably rotated in order to inhibit adhesion of bubbles to a wafer surface, but if the bubble adhesion can be inhibited by some specially devised immersion method or the like, the wafer W may be immersed in the plating solution while not being rotated.

Subsequently, while the wafer W is immersed in the plating solution, the supply rate of the plating solution and the rotation speed of the wafer W are kept at 15 L/ min or higher and 50 rpm or lower respectively. Consequently, the plating film 4 is formed so as to be buried in the narrow wiring trenches 1A and the wide wiring trenches 1B. Here, the rotation speed of the wafer W need not be constant all through the plating film deposition, but may be varied within a range of 50 rpm or lower, or the rotation of the wafer W may be temporarily stopped. That is, it is only necessary that, when at least part of each of the narrow wiring trenches 1A and wide wiring trenches 1B is buried with the plating film 4, the plating solution is supplied for plating at the supply rate of 15 L/min or higher while rotating the wafer W at the rotation speed of 50 rpm or lower. Incidentally, the supply rate of the plating solution can be measured with a flowmeter (not shown) that is installed in a pump 13 for pumping out the plating solution or in a supply pipe 14 or the like for supplying the plating solution pumped out by the pump 13 to the plating solution bath 12.

This embodiment uses a so-called hot entry method in which the wafer W is immersed while the voltage is applied, and thus the plating starts from an immersed portion. Therefore, the rotation speed of the wafer W is preferably 50 rpm or lower also when the wafer W is immersed. It has been conventionally thought that, if a wafer W is in contact with a plating solution while being rotated at a low rotation speed, bubbles are formed on a surface of the wafer W to deteriorate uniformity in the surface of the plating film 4. However, our experiments have shown that the bubble formation can be inhibited even when the wafer W is in contact with the plating solution while being rotated at a rotation speed in a range higher than 0 rpm and not higher than 50 rpm. Therefore, deterioration in uniformity in the surface of the plating film 4 can be inhibited.

After the plating film 4 is formed on the seed film 3, the wafer W is heat-treated to grow crystals of the seed film 3 and the plating film 4, so that a wiring film 6 is formed (Step 6b).

After the wiring film 6 is formed, polishing by, for example, CMP, is performed so as to remove unnecessary portions of the barrier metal film 2 and the wiring film 6 on the interlayer insulation film 1 but leave the barrier metal film 2 and the wiring film 6 existing in the narrow wiring trenches 1A and the wide wiring trenches 1B (Step 7b). Through these processes, narrow wirings 6A each with a line width of 0.3 μm or less and wide wirings 6B each with a line width of more than 0.3 μm are formed.

According to this embodiment, it is possible to lower the impurity concentration in the wide wiring trenches 1B, so that the wide wirings 6B with a reduced number of defects can be formed. In addition, the effect of additives can be obtained, so that it is possible to bury the plating film 4 in the narrow wiring trenches 1A by bottom-up deposition. Specifically, when the wafer W is rotated, a diffusion layer is formed on a surface of the wafer W. The thickness of the diffusion layer is expressed by the following Levich expression (1) regarding a rotating electrode.
δ=1.61 Dₒ^{1/3}ν^{1/6}ω^{-1/2} (1)

Here, D₀ is a coefficient of diffusion, ν is a coefficient of viscosity of a solution, and ω is an angular speed. This expression shows that the lower the rotation speed of the wafer is, the larger the thickness δ of the diffusion layer is.

At an initial stage of the plating, electric current density is adjusted to about 10 mA/cm² in order to ensure a burying property in the minimum line width. Under this condition, Cu ions in the plating solution exist in a sufficient amount and thus are in a reaction rate-determining state. Therefore, it is thought that the concentration of the Cu ions (Cu ion concentration) is also substantially constant in the diffusion layer. On the other hand, the additives exhibit an effect only with a small amount, and thus the concentration of the additives in the plating solution (additive concentration) is far smaller than that of the Cu ions, and the additives are in a diffusion rate-determining state on the surface of the wafer W. Therefore, it can be thought that the additive concentration in the diffusion layer presents a substantially linear concentration gradient.

As shown in FIG. 7, when the rotation speed of the wafer W is about 100 rpm, the thickness of the diffusion layer becomes small, and thus the additive concentration in the vicinity of the surface of the wafer W increases, which results in high impurity concentration in the plating film 4. On the other hand, as shown in FIG. 6 and FIG. 8, when the rotation speed of the wafer W is 50 rpm or lower, the thickness of the diffusion layer becomes large, and thus the additive concentration in the vicinity of the surface of the wafer W becomes low. Accordingly, an amount of the additives taken into the plating film 4 is reduced, so that the impurity concentration in the plating film 4 can be lowered. Therefore, the wide wirings 6B with a reduced number of defects can be formed.

However, when the supply rate of the plating solution is lower than 15 L/min, the adhesion of the additives is promoted on the surface of the wafer W in the plating solution pooled in the plating solution bath 12 to lower the additive concentration outside the diffusion layer as shown in FIG. 8. As a result, the additive concentration on the surface of the wafer W becomes lower than a necessary amount, so that the effect of the additives cannot be obtained. On the other hand, when the plating solution is supplied at the supply rate of 15 L/min or higher, the additives become in a diffusion rate-determining state in the diffusion layer, so that the additive concentration outside the diffusion layer can be maintained substantially constant as shown in FIG. 6. Consequently, the effect of the additives can be obtained, so that the plating film 4 can be buried in the narrow wiring trenches 1A by the bottom-up deposition.

### EXPERIMENTAL EXAMPLE 2

Hereinafter, an experimental example 2 will be described. In this experimental example, defect densities of narrow wirings and wide wirings were measured and a reliability test of the wide wirings was conducted. Further, the state of a wafer surface when the wafer is in contact with a plating solution was observed.

In this experimental example, a plurality of 300 mm wafers having narrow wirings each with a line width of 0.09 μm and wide wirings each with a line width of 0.5 μm were prepared through the procedure described in the second embodiment, and the defect densities of the narrow wirings and the wide wirings of each of the wafers were measured and the reliability test of the wide wirings was conducted. Here, each plating film was formed under the conditions in which the supply rate of the plating solution was set to 20 L/min and the wafers were rotated at different rotation speeds. Further, when the plating film was formed, the surface state of each of the wafers when the wafer was brought into contact with the plating solution was observed.

The results will be discussed below. FIG. 9 is a graph showing the correlation between the rotation speed of the wafer and the defect density according to the experimental example 2. As shown in FIG. 9, even the change in the rotation speed of the wafer causes substantially no change in the defect density in the narrow wirings, but in the wide wirings, the defect density becomes lower as the rotation speed of the wafer gets lower. It has been confirmed from this result that the narrow wirings are given substantially no influence by the rotation speed of the wafer, while the lower rotation speed of the wafer is more preferable for the wide wirings. Further, it has been also confirmed in the reliability test of the wide wirings that the lower rotation speed of the wafer is more preferable.

Further, regarding the surface state of the wafer when the wafer was brought into contact with the plating solution, substantially no bubble was formed. It has been confirmed from this result that, even when the wafer is brought into contact with the plating solution while being rotated at the rotation speed of higher than 0 rpm and not higher than 50 rpm, the deterioration in uniformity in the surface of the plating film can be inhibited.

### Third Embodiment

Hereinafter, a third embodiment will be described. This embodiment will describe an example where a barrier metal film is made of a metal which belongs to one of group 2A, group 4A, group 5A, group 6A, and group 2B and is capable of forming the reactant with the metal that is the main component of a plating film. Some of the same contents as those of the first embodiment will be omitted.

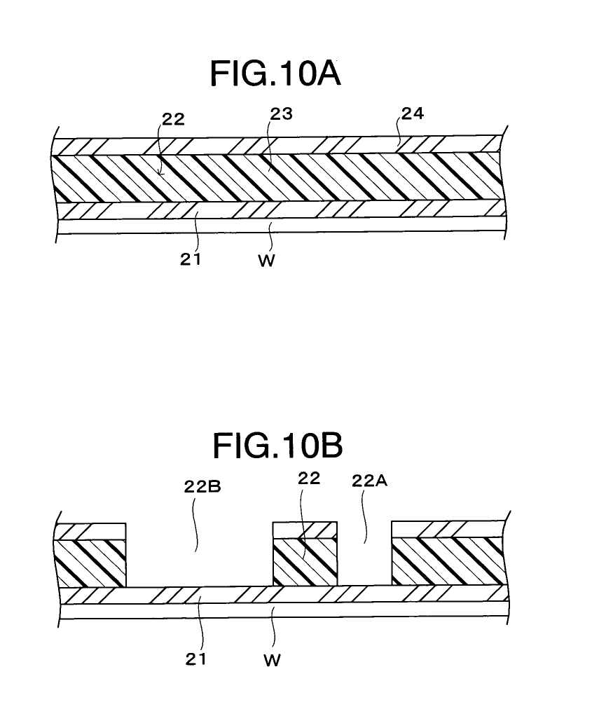

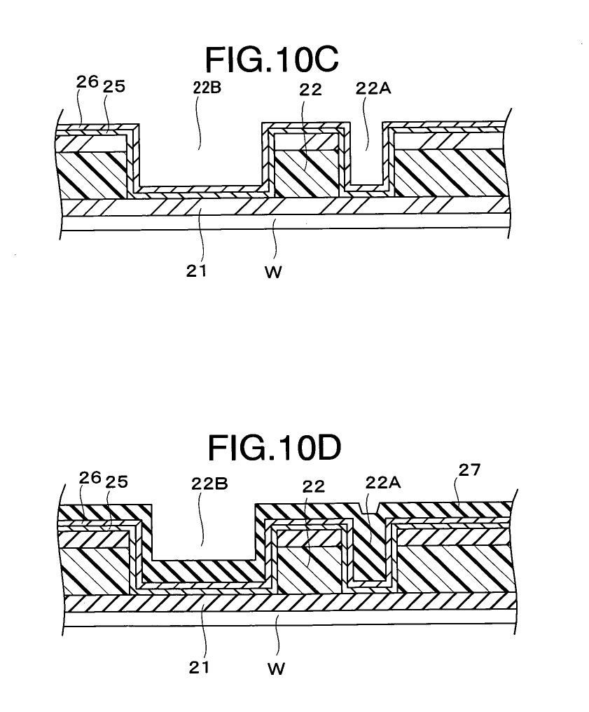

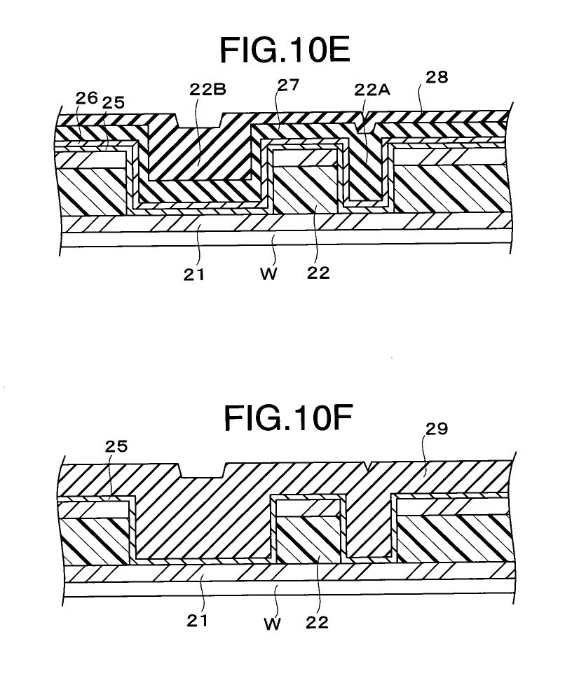

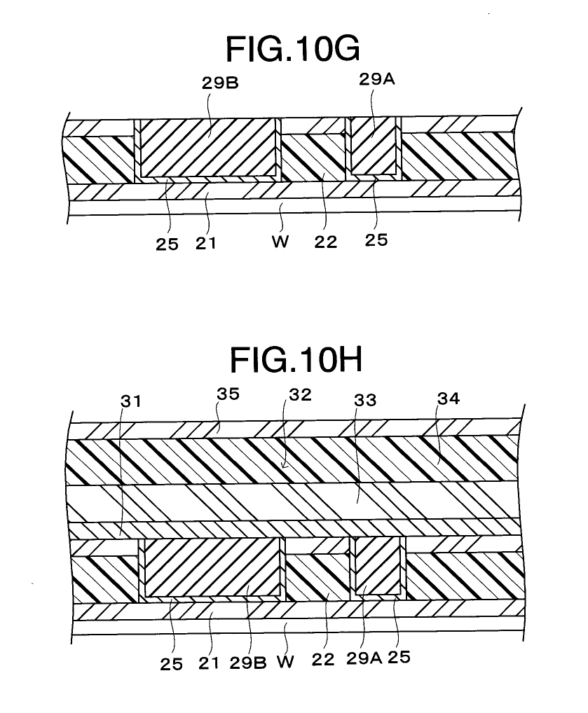

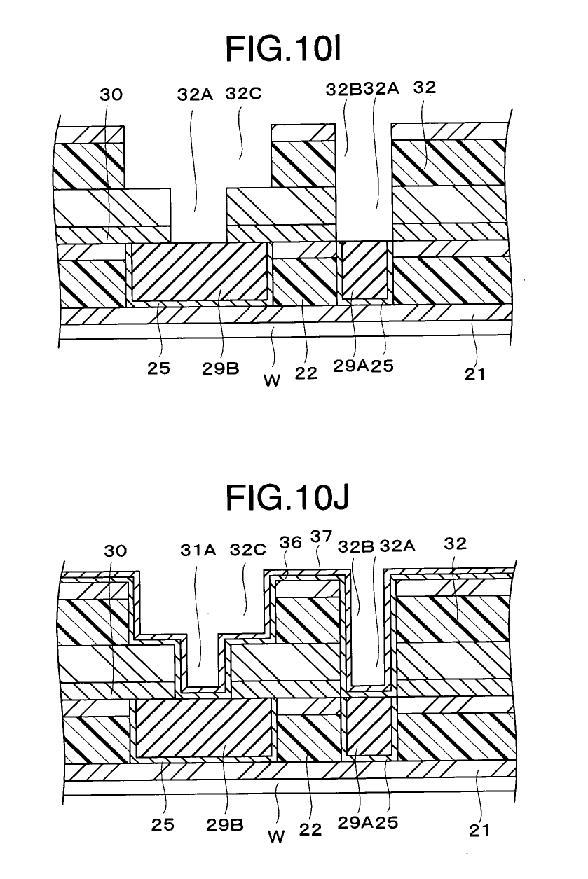

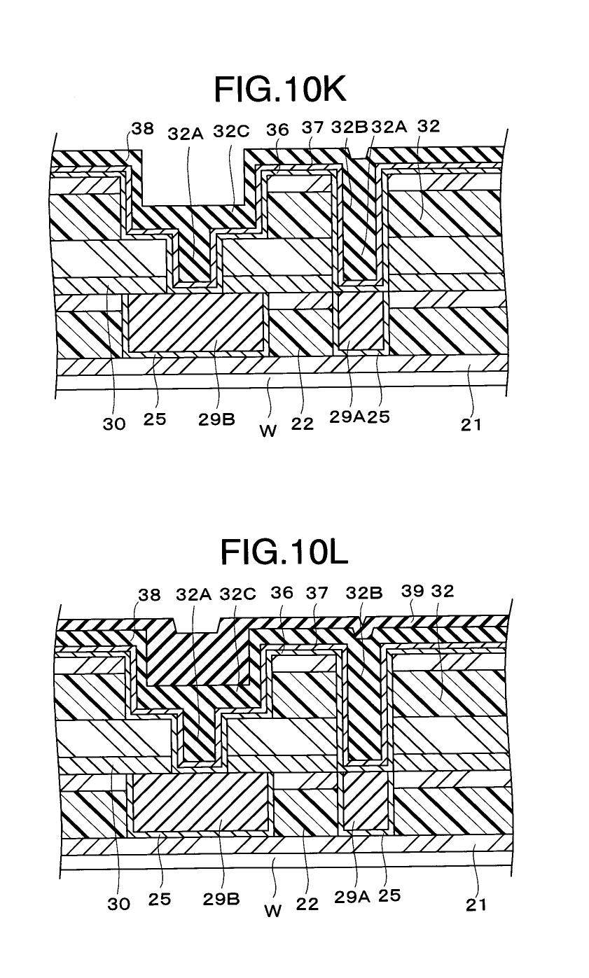

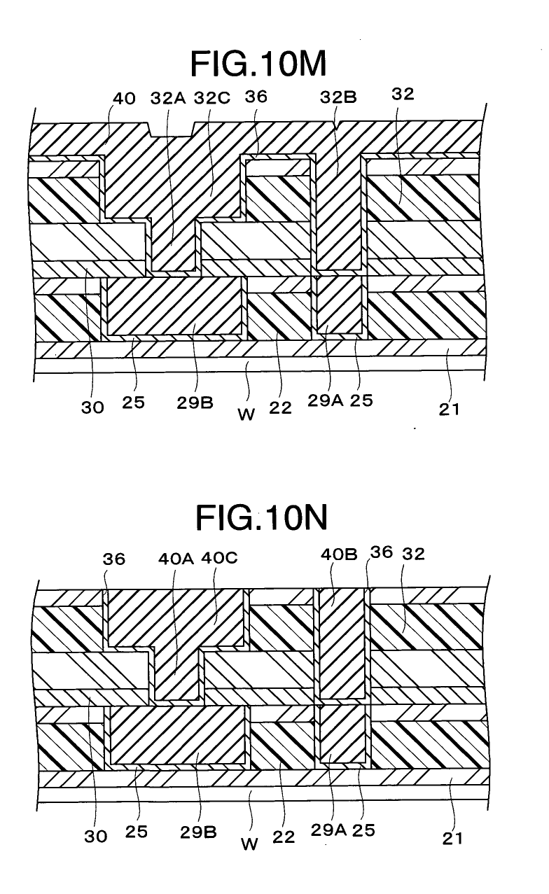

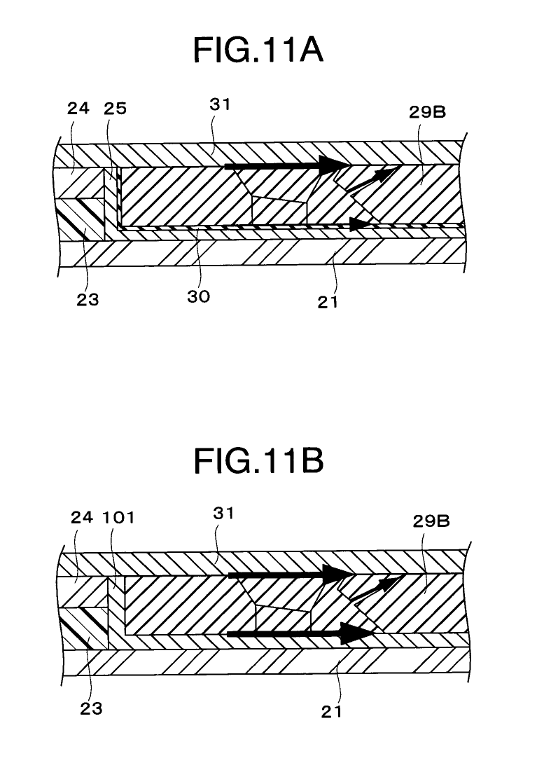

FIG. 10A to FIG. 10N are schematic views showing manufacturing processes of a semiconductor device according to this embodiment. FIG. 11A is a view schematically showing a state of an interface between a wide wiring and the barrier metal film when a main component of the wide wiring is Cu and the barrier metal film is composed of Ti, according to the third embodiment, and FIG. 11B is a view schematically showing a state of an interface between a wide wiring and a barrier metal film when a main component of the wide wiring is Cu and the barrier metal film is composed of Ta.

As shown in FIG. 10A, an interlayer insulation film 22 is formed on a SiO₂ film 21 with a not-shown exposed lower electrode. In this embodiment, the interlayer insulation film 22 is composed of a polyarylene ether film 23 (hereafter, referred to as a “PAE film”) being an organic low dielectric constant insulation film and a SiO₂film 24 formed on the PAE film 23. The SiO₂film 24 also functions as a protective film in CMP. Incidentally, in this embodiment, the PAE film 23 and the SiO₂ film 24 are used as the interlayer insulation film 22, but the interlayer insulation film 22 is not limited to such composition, but for example, the interlayer insulation film 1 described in the first embodiment can also be used.

After the interlayer insulation film 22 is formed on a wafer W, narrow wiring trenches 22A each with a width of 0.3 Mm or less and wide wiring trenches 22B each with a width of more than 0.3 μM are formed in the interlayer insulation film 22 as shown in FIG. 10B, by a photolithography technique and reactive ion etching (RIE).

After the narrow wiring trenches 22A and the wide wiring trenches 22B are formed in the interlayer insulation film 22, a barrier metal film 25 is formed on the interlayer insulation film 22 as shown in FIG. 10C. The barrier metal film 25 is composed of one or more metal selected from metals which belong to one of group 2A, group 4A, group 5A, group 6A, and group 2B and are capable of forming a reactant with a metal that is the main component of a later-described plating film 27. Examples of the metals which belong to one of group 2A, group 4A, group 5A, group 6A, and group 2B and are capable of forming a reactant with a metal that is the main component of the plating film 27 are Mg, Ti, V, Zn, Zr, Hf, and W. Among these metals, Ti is preferable.

After the barrier metal film 25 is formed on the interlayer insulation film 22, a seed film 26 is formed on the barrier metal film 25 as shown in FIG. 10C. The seed film 26 is formed so as to be in direct contact with the barrier metal film 25 and its main component is the same metal as the metal that is the main component of the plating film 27.

After the seed film 26 is formed on the barrier metal film 25, a plating solution is supplied to a surface of the seed film 26 and at the same time, electric current is supplied to the seed film 26, so that a plating film (first metal film) 27 is formed by electrolytic plating as shown in FIG. 10D. In this embodiment, the plating film 27 is formed so as to be buried in the whole of each of the narrow wiring trenches 22A and in part of each of the wide wiring trenches 22B. An example of the metal that is the main component of the plating film 27 is at least one of Cu, Ag, and Au.

After the plating film 27 is formed on the seed film 26, a sputtering film (second metal film) 28 is formed on the plating film 27 as shown in FIG. 10E, by, for example, sputtering. The sputtering film 28 is formed so as to be buried in the other part of each of the wide wiring trenches 22B. A main component of the sputtering film 28 is the same metal as the metal that is the main component of the plating film 27 and its impurity concentration is lower than the impurity concentration in the plating film 27.

After the sputtering film 28 is formed on the plating film 27, the wafer W is heat-treated, crystals of the seed film 26, the plating film 27, and the sputtering film 28 are grown, so that a wiring film 29 is formed as shown in FIG. 10F.

After the wiring film 29 is formed, polishing by, for example, CMP is performed so as to remove unnecessary portions of the barrier metal film 25 and the wiring film 29 on the interlayer insulation film 22 but leave the barrier metal film 25 and the wiring film 29 existing in the narrow wiring trenches 22A and the wide wiring trenches 22B, as shown in FIG. 10G. Consequently, a first layer wiring having narrow wirings (first wiring) 29A each with a line width of 0.3 μm or less and wide wirings (second wiring) 29B each with a line width of more than 0.3 μm is formed.

After the narrow wirings 29A and the wide wirings 29B are formed, a SiCN film 31 as a stopper film for RIE and a Cu diffusion prevention film, and an interlayer insulation film 32 are formed in sequence on the interlayer insulation film 22 as shown in FIG. 10H. The interlayer insulation film 32 is composed of a SiCO film 33 being an inorganic low dielectric constant insulation film, a PAE film 34 being an organic low dielectric constant insulation film formed on the SiCO film 33, and a SiO₂ film 35 formed on the PAE film 34. The SiO₂ film 35 also functions as a protective film in CMP.

After the SiCN film 31 and soon are formed on the interlayer insulation film 22, via holes 32A, narrow wiring trenches 32B, and wide wiring trenches 32C are formed in the interlayer insulation film 32 as shown in FIG. 10I, by a photolithography technique and reactive ion etching (RIE).

Thereafter, as shown in FIG. 10, a barrier metal film 36 is formed on the interlayer insulation film 32. The barrier metal film 36 is composed of the same metal as that of the barrier metal film 25.

After the barrier metal film 36 is formed on the interlayer insulation film 32, a seed film 37 is formed on the barrier metal film 36 as shown in FIG. 10J. The seed film 37 is formed so as to be in direct contact with the barrier metal film 36, and its main component is the same metal as a metal that is a main component of a later-described plating film 38.

After the seed film 37 is formed on the barrier metal film 36, a plating solution is supplied to a surface of the seed film 37, and at the same time, electric current is supplied to the seed film 37, so that a plating film (first metal film) 38 is formed as shown in FIG. 10K, by electrolytic plating. In this embodiment, the plating film 38 is formed so as to be buried in the whole of each of the via holes 32A, the whole of each of the narrow wiring trenches 32B, and part of each of the wide wiring trenches 32C. An example of the metal that is the main component of the plating film 38 is the same metal as the metal that is the main component of the plating film 27.

After the plating film 38 is formed on the seed film 37, a sputtering film (second metal film) 39 is formed on the plating film 38 as shown in FIG. 10L, by, for example, sputtering. The sputtering film 39 is formed so as to be buried in the other part of each of the wide wiring trenches 32C. A main component of the sputtering film 39 is the same metal as the metal that is the main component of the plating film 38, and its impurity concentration is lower than the impurity concentration in the plating film 38.

After the sputtering film 39 is formed on the plating film 38, the wafer W is heat-treated, and crystals of the seed film 37, the plating film 38, and the sputtering film 39 are grown, so that a wiring film 40 is formed as shown in FIG. 10M.

After the wiring film 40 is formed, polishing by, for example, CMP is performed so as to remove unnecessary portions of the barrier metal film 36 and the wiring film 40 on the interlayer insulation film 32 but leave the barrier metal film 36 and the wiring film 40 in the via holes 32A, the narrow wiring trenches 32B, and the wide wiring trenches 32C, as shown in FIG. 10N. Consequently, a second layer wiring connected to the first layer wiring by via plugs 40A and having narrow wirings (first wiring) 40B each with a line width of 0.3 μm or less and wide wirings (second wiring) 40C each with a line width of more than 0.3 μm is formed. Repeating these processes realizes the formation of wirings on a third layer and further upper layers, if they are to be formed.

A defect directly under a via plug in a dual damascene structure, if any, lowers yields and deteriorates resistance against electromigration (EM) due to a micro void. The method described in the foregoing first embodiment can solve these problems, but in an actual pattern in which wiring width and depth are diversified, a pattern with deteriorated reliability against stress migration (SM) may possibly exist on the other hand.

Specifically, if the impurity concentration in a wiring is too low, metal atoms in the wiring move by diffusion, which may possibly cause further change in particle size of metal particles, not only in heat treatment following the formation of the sputtering film, but also in a post-process of heat treatment and so on for recovering a defect level of a gate insulation film of a MOSFET (Metal Oxide Semiconductor Field Effect Transistor). This is because the low impurity concentration in the wiring lessens factors for inhibiting the diffusive movement of the metalatoms. This is thought to cause deterioration in reliability against stress migration (SM). This phenomenon tends to occur especially in the wide wirings with low impurity concentration.

On the other hand, in this embodiment, the barrier metal film 25 is composed of a metal which belongs to one of group 2A, group 4A, group 5A, group 6A, and group 2B and is capable of forming a reactant with a metal that is the main component of the plating film 27, so that the metal that is the main component of the wide wirings 29B and the metal included in the barrier metal film 25 mutually diffuse, so that an atomic-level diffusion layer including the reactant of the metal being the main component of the wide wirings 29B and the metal included in the barrier metal film 25 is formed on the interfaces between the wide wirings 29B and the barrier metal film 25. Specifically, for example, when the main component of the wide wirings 29B is Cu and the barrier metal film 25 is composed of Ti, a diffusion layer 30 including a reactant of Cu and Ti is formed on the interfaces between the wide wirings 29B and the barrier metal film 25 as shown in FIG. 11A. The formation of the diffusion layer 30 containing such a reactant increases adhesion between the wide wirings 29B and the barrier metal film 25 to inhibit the diffusive movement of the metal atoms on the interfaces between the wide wirings 29B and the barrier metal film 25. Therefore, even when the impurity concentration in the wide wirings 29B is low, the deterioration in reliability against stress migration can be inhibited, and as a result, inhibiting the deterioration in reliability against the stress migration and reducing defects can be both realized in the wirings. When, on the other hand, the main component of the wide wirings 29B is Cu and the barrier metal film is composed of Ta that is a metal which is incapable of forming a reactant with the metal that is the main component of the plating film 27, no diffusion layer including a reactant of Cu and Ta is formed on the interfaces between the wide wirings 29B and a barrier metal film 101 as shown in FIG. 11B, and thus no such effect as described above is obtainable.

A diffusion layer including such a reactant as described above is formed between the narrow wirings 29A and the barrier metal film 25, between the via plugs 32A and the barrier metal film 36, between the narrow wirings 32B and the barrier metal film 36, and between the wide wirings 32C and the barrier metal film 36, besides between the wide wirings 29B and the barrier metal film 25, and therefore, the same effect as the aforesaid effect can be obtained there.

In this embodiment, used are the barrier metal films 25, 36 each composed of a metal which belongs to one of group 2A, group 4A, group 5A, group 6A, and group 2B and is capable of forming the reactant with the metal that is the main component of the plating film 27, 38, but other film may be used instead of the barrier metal films if it includes such a metal and is in direct contact with the seed films 26, 37.

As long as the barrier metal films 25, 36 include a metal which belongs to one of group 2A, group 4A, group 5A, group 6A, and group 2B and is capable of forming the reactant with the metal that is the main component of the plating film 27, 38, they may include other metal which is incapable of forming the reactant with the metal that is the main component of the plating film 27, 38. Examples of the metal which is incapable of forming the reactant with the metal that is the main component of the plating films 27, 38 are Ta, TaN, or the like.

Moreover, as long as the barrier metal film 25 is formed in direct contact with the seed film 26, or the barrier metal film 36 is formed in direct contact with the seed film 37, other barrier metal film may be formed between the interlayer insulation film 22 and the barrier metal film 25, or between the interlayer insulation film 32 and the barrier metal film 36. In this case, the other barrier metal film may be composed of a metal which is incapable of forming the reactant with the metal that is the main component of the plating films 27, 28 and the sputtering films 28, 29. In this case, in the state where the first layer wirings and the second layer wirings are formed, the barrier metal films 25, 36 are formed on the wide wiring 29B, 40C side and the other barrier metal film is formed on the interlayer insulation film 22, 23 side, between the interlayer insulation films 22, 32 and the wide wirings 29B, 40C.

It should be noted that the present invention is not limited to the embodiments and the contents of the description above, but any appropriate change may be made in the structure, material, and arrangement and so on of the members without departing from the spirits of the present invention. For example, in the first and second embodiments, the wiring does not have a multilayer structure, but may have the multilayer structure as in the third embodiment, or conversely, the wiring in the third embodiment need not have a multilayer structure.

1. A method of manufacturing a semiconductor device, comprising:
forming a first metal film on a substrate having a recessed portion in a surface thereof, by a plating method so as to bury the first metal film in at least part of the recessed portion;
forming a second metal film on the first metal film by a film deposition method different from the plating method, the second metal film including, as a main component, a metal that is a main component of the first metal film and containing an impurity whose concentration is lower than concentration of an impurity contained in the first metal film;
heat-treating the first and second metal films; and
removing the first and second metal films except portions buried in the recessed portion after said heat treatment.

2. The method of manufacturing the semiconductor device as set forth in claim 1, wherein the first metal film is formed so as to be buried in part of the recessed portion and the second metal film is formed so as to be buried in the other part of the recessed portion.

3. The method of manufacturing the semiconductor device as set forth in claim 1, wherein the film deposition method is one of sputtering and chemical vapor deposition.

4. The method of manufacturing the semiconductor device as set forth in claim 1, wherein a component with the highest concentration among components of the impurity contained in the second metal film has concentration of 1.00×10^{17 atom/cm}³ or lower.

5. The method of manufacturing the semiconductor device as set forth in claim 1, wherein the main component of the first metal film is one of copper (Cu), silver (Ag), and gold (Au).

6. The method of manufacturing the semiconductor device as set forth in claim 1, wherein the impurity is a substance having at least one of sulfur (S), chlorine (Cl), oxygen (O), carbon (c), and nitrogen (N).

7. The method of manufacturing the semiconductor device as set forth in claim 1, further comprising prior to said forming the first metal film:
forming, at least on an inner surface of the recessed portion, a film containing one or more metal selected from metals which belong to one of group 2A, group 4A, group 5A, group 6A, and group 2B and are capable of forming a reactant with a metal that is the main component of the first metal film; and
forming a seed film whose main component is a metal that is the main component of the first metal film, so as to bring the seed film in direct contact with the film formed on the inner surface of the recessed portion,
wherein said forming the first metal film is performed while supplying electric current to the seed film.

8. The method of manufacturing the semiconductor device as set forth in claim 7, wherein the metals which belong to one of the group 2A, group 4A, group 5A, group 6A, and group 2B and are capable of forming the reactant with the metal that is the main component of the first metal film are magnesium (Mg), titanium (Ti), vanadium (V), zinc (Zn), zirconium (Zr), hafnium (Hf), and tungsten (W).

9. The method of manufacturing the semiconductor device as set forth in claim 7, wherein the main component of the first metal film is copper (Cu), and the one or more metal selected from the metals which belong to one of the group 2A, group 4A, group 5A, group 6A, and group 2B and are capable of forming the reactant with the metal that is the main component of the first metal film is titanium (Ti).

10. A method of manufacturing a semiconductor device, comprising:
immersing a substrate having a recessed portion in a surface thereof, in a plating solution in a plating solution bath, and supplying the plating solution into the plating solution bath at a supply rate of 15 L/min or higher while rotating the substrate at a rotation speed of 50 rpm or lower, thereby forming a metal film on the substrate by a plating method so as to bury the metal film in at least part of the recessed portion; and
removing the metal film except a portion buried in the recessed portion.

11. The method of manufacturing the semiconductor device as set forth in claim 10, wherein said immersing the substrate in the plating solution is performed while voltage is applied between the substrate and an anode.

12. The method of manufacturing the semiconductor device as set forth in claim 10, wherein said immersing the substrate in the plating solution is performed while the substrate is being rotated at a rotation speed of higher than 0 rpm and not higher than 50 rpm.

13. A semiconductor device comprising:
a substrate;
an insulation film formed above said substrate and having a first recessed portion and a second recessed portion in a same surface;
a first wiring buried in the first recessed portion and having a line width of 0.3 μm or less; and
a second wiring buried in the second recessed portion, having a line width of more than 0.3 μm, and containing an impurity whose concentration is lower than concentration of an impurity contained in said first wiring.

14. The semiconductor device as set forth in claim 13, wherein the concentration of the impurity in said first wiring is 5×10¹⁸ atom/cm³ to 1×10¹⁹ atom/cm³, and the concentration of the impurity in said second wiring is lower than 5×10¹⁸ atom/cm³.

15. The semiconductor device as set forth in claim 13, wherein said first wiring has a line width of not less than 0.05 μm nor larger than 0.3 μm, and said second wiring has a line width of larger than 0.3 μm and not larger than 10 μm.

16. The semiconductor device as set forth in claim 13, wherein a main component of each of said first wiring and said second wiring is one of copper (Cu), silver (Ag), and gold (Au).

17. The semiconductor device as set forth in claim 13, wherein the impurity is a substance having at least one of sulfur (S), chlorine (Cl), oxygen (O), carbon (c), and nitrogen (N).

18. The semiconductor device as set forth in claim 13, further comprising:
a film containing at least one or more metal selected from metals which belong to one of group 2A, group 4A, group 5A, group 6A, and group 2B and are capable of forming a reactant with a main component of said second wiring, and interposed between an inner surface of the second recessed portion and said second wiring; and
a diffusion layer provided on an interface between said second wiring and said film, formed by mutual diffusion of the main component of said second wiring and the metal contained in said film, and containing the reactant of the main component of said second wiring and the metal contained in said film.

19. The semiconductor device as set forth in claim 18, wherein the metals which belong to one of the group 2A, group 4A, group 5A, group 6A, and group 2B and are capable of forming the reactant with the main component of said second wiring are magnesium (Mg), titanium (Ti), vanadium (V), zinc (Zn), zirconium (Zr), hafnium (Hf), and tungsten (W).

20. The semiconductor device as set forth in claim 18, wherein the main component of said second wiring is copper (Cu), and the one or more metal selected from the metals which belong to one of the group 2A, group 4A, group 5A, group 6A, and group 2B and are capable of forming the reactant with the main component of said second wiring is titanium (Ti).
